(19) United States
(12) Patent Application Publication
(10) Pub. No.: US 2026/0126720 A1
(43) Pub. Date: May 7, 2026

(54) SAMPLE DAMAGE AVOIDANCE IN DEVICES AND METHODS FOR SAMPLE PROCESSING AND SAMPLE REPAIR

(71) Applicant: Carl Zeiss SMT GmbH, Oberkochen (DE)

(72) Inventors: Rene Kullock, Darmstadt (DE); Hans Hermann Pieper, Schaafheim (DE); Christof Baur, Darmstadt (DE); Robert Heberlein, Laudenbach (DE)

(21) Appl. No.: 19/379,888

(22) Filed: Nov. 5, 2025

(30) Foreign Application Priority Data
Nov. 5, 2024 (DE) 102024132213.6

(51) Int. Cl. G03F 1/86; G03F 1/72

(52) U.S. Cl. CPC G03F 1/86; G03F 1/72

(57) ABSTRACT

A method for potential determination pertaining to a sample comprises: positioning a probe above the sample; applying at least a first and a second DC voltage offset each from a first range; applying an AC voltage to the probe for the purpose of inducing a mechanical oscillation of the probe; determining a first induced deflection of the probe for the first DC voltage offset and a second induced deflection of the probe for the second DC voltage offset; and determining a potential outside an interval spanned by the first and second DC voltage offsets at least partly on the basis of the first and second deflections. A method for causing approach by a probe towards a sample comprises: causing approach by the probe towards the sample; repeatedly determining a deflection of the probe during the process of causing approach; and ascertaining an approach termination condition for avoiding sample damage at least partly on the basis of the deflection of the probe or the oscillation frequency thereof.

### CROSS-REFERENCE TO RELATED APPLICATION

The present application claims priority to German patent application 10 2024 132 213.6, filed on Nov. 5, 2024, which is hereby incorporated by reference in its entirety.

### TECHNICAL FIELD

The present invention relates to methods for potential determination pertaining to a sample, methods for causing approach by a probe towards a sample, methods for processing a sample, and also corresponding devices and computer programs.

### BACKGROUND

As a result of constantly increasing integration density in microelectronics, there is a need for substrates, for example, lithographic masks, mask blanks or wafers, to have ever better surfaces. For example, lithographic masks are intended to image ever smaller structural elements into a photoresist layer of a wafer. This is likewise true of templates that are used in nanoimprint lithography. In order to meet these requirements, the exposure wavelength is being shifted to ever shorter wavelengths. The trend is towards ever shorter wavelengths that extend into the extreme ultraviolet (EUV) wavelength range (10 nm to 15 nm) and towards corresponding EUV masks.

It is frequently the case that defects occur in the production of masks because of the ever decreasing dimensions of the structural elements. Since production is associated with high costs, defective photomasks, photolithographic masks, and likewise the templates used in nanoimprint lithography are repaired whenever possible.

In the repair of photomasks, parts of an absorber pattern that exist at positions on the mask that are not envisaged by the design may be removed. In addition, absorbing material may be deposited at positions on the mask that are free of absorbing material even though the mask design envisages absorbing pattern elements. Both types of repair processes can create debris fragments or particles that can settle at opaque, transparent or reflective sites on photomasks and cause imaging aberrations in lithographic exposure that are visible on a structured wafer.

A further problem is particles from the environment that settle on the surface of a mask or another substrate or on components of a photolithographic exposure system. Moreover, the handling of a mask during the process for production thereof and/or operation thereof can create particles that can settle on the mask.

There are two further difficulties in the case of photolithographic exposure systems that work with electromagnetic radiation in the EUV wavelength range. For EUV masks, there is currently no satisfactory protection (for instance a pellicle) for the surface thereof that bears structure elements. As a result, EUV masks are particularly prone to the settling of particles on this structured surface. Secondly, an EUV radiation source typically uses tin plasma for producing the EUV radiation. Particles from the hot plasma can be deposited on components of an EUV exposure system, especially on the optical components or elements thereof, including the EUV mask, and can impair the function thereof.

The decreasing structural dimensions of photolithographic masks are increasing the difficulty of cleaning processes. Moreover, as a result of the decreasing exposure wavelength, increasingly smaller foreign particles or dirt particles adhering on the surface of the mask or of an optical element of the exposure system are becoming visible on a wafer in an exposure process.

In view of ever smaller structures, tailored solutions are becoming increasingly important for processing and cleaning of masks and—more generally—substrates. In particular, it may be necessary to eliminate various defects on the same substrate with an acceptable level of cost and inconvenience. The processing of surfaces, especially the moving of particles and the lifting and/or removal of individual particles from a surface, is typically a difficult and time-consuming process. External constraints can limit the tools and treatment options available. Moreover, it can be costly and inconvenient to completely remove a particle adhering on a surface of a substrate from the substrate.

Typically, processing a sample necessitates causing approach by a probe towards the sample, although this is not always possible without problems, for the following reasons:

During processes for loading the sample into a vacuum, e.g., evacuating and measuring processes may cause the sample to become electrostatically charged. In the course, too, of viewing samples (e.g., photomasks) in a scanning electron microscope (SEM), the sample may likewise be charged by the introduced electrons of the primary beam and also by the secondary electrons (SE). The charging behavior may be dependent here primarily on the SE yield (SEY). Samples having large conductive structures which are not or cannot be electrically contacted are critical in both cases. These include, e.g., so-called “chrome on glass blanks” for particle monitoring tests and EUV masks. EUV masks, as high-end mask types, are particularly expensive and are particularly sensitive to particle contamination and electrostatic discharge (ESD) owing to their small structures.

By way of example, if a probe (e.g., an AFM tip) is brought into contact with an electrically charged sample or is guided into the vicinity thereof, the sample may be discharged via the tip (in a so-called ESD event), which may lead to damage to the sample and also the probe.

Therefore, the present invention is based on the general aspect of at least partly improving corresponding methods, devices and computer programs.

### SUMMARY

This general aspect is at least partly achieved by the aspects described herein.

A first aspect of the present invention relates to a method for potential determination pertaining to a sample, wherein the method comprises: positioning a probe above the sample; applying at least a first and a second DC voltage offset each from a first range; applying an AC voltage to the probe for the purpose of inducing a mechanical oscillation of the probe; determining a first induced deflection of the probe for the first DC voltage offset and a second induced deflection of the probe for the second DC voltage offset; and determining a potential (also referred to herein as sample potential or potential of the sample) outside an interval spanned by the first and second DC voltage offsets at least partly on the basis of the first and second deflections.

The inventors have recognized that the present situation is suitable for making use of the following physical relationship: Acting between two objects spaced apart from one another in the z-direction with finite potential difference ΔV there is an electrical force

$${F}_{e l} = - \frac{1}{2} \frac{\partial C}{\partial z} {( Δ V )}^{2}$$

with the electrical capacitance C˜z⁻¹. The corresponding force gradient is

$${F}_{e l}^{′} = \frac{\partial {F}_{e l}}{\partial z} .$$

If a DC voltage offset V_{DC} is applied so that the potential difference ΔV vanishes, there is no acting electrical force Fₑₗ.

If a DC voltage offset V_{DC} and a temporally variable AC voltage V_{AC} sin(ωt) are applied, this generally results in the temporally variable force

$${F}_{e l} ( t ) = - \frac{1}{2} \frac{\partial C}{\partial z} {( {V}_{D C} + {V}_{A C} sin ( ω t ) - {V}_{C P D} )}^{2} ,$$

wherein V_{CPD} represents the contact potential or sample potential, i.e., the potential difference corresponding to the work function difference ΔΦ between the two aforementioned objects, divided by the elementary charge e: V_{CPD}=ΔΦ/e.

The two aforementioned objects herein may be, e.g., a sample and a probe.

As illustrated schematically in FIG. 1A, the force acting on the probe can be well approximated by a harmonic function 110. FIG. 1A shows, in particular, that the force as a function of the voltage (of the DC voltage offset and the AC voltage) between sample and probe (see FIG. 1B) follows a parabola. It can be discerned here that applying a DC voltage offset 121 so that V_{DC}−V_{CPD}=0 corresponds to the vertex of the parabola. As described herein, the constant V_{CPD} corresponds to the contact potential or potential of the sample which is intended to be determined, and V_{DC} corresponds to the applied DC voltage offset. At the vertex, the parabola has a gradient of approximately zero, and so an applied AC voltage 131 with the frequency f_{mod} cannot induce a strong force 141 between probe and sample. On the contrary, the latter tends towards zero. Moreover, on account of the zero crossing (and the associated change of sign) in the voltage of the applied voltage 131, the frequency would have the effect that the frequency of the induced force (with amplitude tending towards zero) is 2·f_{mod}. Since this frequency is far away from the resonant frequency of the probe, the probe cannot be excited (or can be excited only with great difficulty) to oscillate there, which furthermore contributes to the force amplitude and the oscillation amplitude approaching zero.

In the case of a different, e.g. higher, DC voltage offset 122 so that (V_{DC}−V_{CPD})²>0, an applied AC voltage 132 (e.g., with identical or different amplitude and/or frequency) leads to a relatively greater deflection or amplitude of the induced oscillation 142. This is evident from the fact that the parabola has a gradient that is not equal to zero at all points apart from its vertex.

Previously known methods have been able hitherto only to determine sample potentials for voltage ranges in which it is also possible to apply a voltage. Therefore, if there were a desire to use these conventional methods to measure/determine potentials of a sample, e.g., of a mask voltage, e.g., in the range of −63 V to +63 V that is often technically relevant, this would require having to “sweep”, e.g., from −75 V to +75 V (in any case at least from −63 V to +63 V) (i.e., to apply DC voltage offsets and/or to vary them systematically over a predetermined range, for example continuously or in discrete steps, as described in greater detail herein) spanning this voltage range. This would be problematic from three standpoints: Firstly, such wide DC voltage offset ranges need an additional amplifier for higher voltages and a compatible mixer. This makes the method and corresponding devices more complicated, increases costs and makes the method more susceptible. Secondly, typical controllers exhibit breakdown strength only up to 42 V, i.e., if there were a short circuit, this may lead to (irreparable) damage to the probe, sample, device, etc. Thirdly, above 50 V marks a departure from the extra-low voltage range, which is safety-relevant and entails additional certifications. All these problems can be avoided by the present invention. The latter, by way of steps described herein, can determine the potential outside the interval spanned by the first and second DC voltage offsets, which simplifies the method, makes the method safer, accelerates the method and reduces costs.

Tests have shown that with the method according to the invention, DC voltage offset ranges of −200 V to +200 V can be covered well and only errors of less than ˜10% are obtained in the process.

Consequently, it is possible to address disadvantages of conventional methods in regard to the following problems: Firstly, the problem that the sample potential is not known exactly is typically encountered, and so the larger accessible measurement range can be helpful. Secondly, if the potential difference between sample and probe is too large, both probe and sample are damaged (often irreparably). Particularly in the case of expensive samples such as, e.g., EUV masks, even very small voltage differences (˜20 V) that may arise, e.g., as a result of the loading of the sample are sufficient to produce irreparable damage. Such voltage differences can be determined reliably.

In one preferred embodiment, the first DC voltage offset can be applied at a first point in time and the second DC voltage offset can be applied at a second point in time (different from the first point in time) (e.g., temporally before or after the first point in time). Applying at least the first and second DC voltage offsets can comprise “sweeping”:

The applied voltage varies/changes during a so-called “sweep”. The applied voltage can typically change continuously or in discrete (e.g., equidistant) steps from a minimum to a maximum (or vice versa) in an interval that is predefined and/or determined by a user or the device. Consequently, in a “sweep” or during “sweeping”, a plurality of voltages (herein, e.g., DC voltage offsets) will be applied temporally successively. The so-called “sweeping” can proceed as follows, for example, in the context of applying the first and second DC voltage offsets: In one example, the first DC voltage offset corresponds to the minimum of a sweep interval and the second DC voltage offset corresponds to the maximum of the sweep interval. As described herein, the first DC voltage offset can be applied at a first point in time and the second DC voltage offset can be applied at a second point in time (different from the first point in time) (e.g., temporally before or after the first point in time). In the time between the first and second points in time, the applied voltage can be swept, that is to say that it can be varied continuously or in discrete steps from the first DC voltage offset to the second DC voltage offset (or the other way around).

Applying the AC voltage can take place temporally during the first and second points in time, for example. In this regard, for example, the first DC voltage offset and the AC voltage can be applied at the first point in time and the second DC voltage offset and the AC voltage can be applied at the second point in time.

In one exemplary embodiment, the deflection can comprise an amplitude of the mechanical oscillation and/or a phase of the mechanical oscillation.

The inventors have recognized that precisely the amplitude and phase of the oscillation are suitable for being able to carry out the process of determining the potential with particularly high accuracy and reliability.

By way of example, the first and second deflections can comprise an in-phase component and/or a quadrature component.

The use of the in-phase component and/or the quadrature component can further simplify the method or make it more efficient. Instead of analyzing, e.g., the demodulated amplitude signal, e.g., the in-phase component and/or the quadrature component can be analyzed (e.g., fitted), each of which can exhibit a very good linear profile, which can greatly simplify and accelerate succeeding analysis steps and/or increase the accuracy and/or reliability thereof.

In one example, determining the first and second deflections can comprise a lock-in amplification.

Precisely in combination with the use of the in-phase component and/or the quadrature component as described herein, this can be particularly advantageous since the in-phase component and/or the quadrature component can be provided directly by conventional lock-in amplifiers. Whereas conventional methods do not use the signals available by virtue of the mode of operation of the lock-in amplifiers, the inventors have recognized that these signals facilitate, e.g., subsequent evaluation (e.g., fitting).

In principle, a lock-in amplifier is, e.g., advantageous for measuring weak signals that may be embedded, e.g., in a highly noisy background. The lock-in amplifier can be configured, e.g., to extract a signal by mixing it with a reference frequency and analyzing the resulting components. These components can be or comprise the in-phase component described herein (also designated herein as “X”) and the quadrature component (also designated herein as “Y”).

For example, the AC voltage frequency can be substantially equal to or a multiple of a resonant frequency of the probe. Further, in some examples, the reference frequency may be substantially equal to the AC voltage frequency.

Precisely a resonant excitation can be particularly suitable since, as a result, high amplitudes can be attained and large differences in the deflection can thus be observed even when there are small differences in the DC voltage offset. That can simplify and accelerate the method and make it more accurate.

In one exemplary embodiment, the first range can extend from −10 V to +10 V.

In view of the problems with conventional methods for potential determination as described herein, precisely the range of −10 V to +10 V is particularly advantageous: Instead of expanding the sweep range in order to be able to examine the largest possible voltage ranges, the present invention can comprise varying the DC voltage offset in the (comparatively small) range of −10 V to +10 V, which corresponds to the typical output range of a controller used for corresponding devices.

For example, determining the potential can comprise fitting, using a fit function, at least a first data point comprising the first deflection and the first DC voltage offset and a second data point comprising the second deflection and the second DC voltage offset.

The method can comprise, e.g., fitting the data points (e.g., 10 or more, 100 or more, etc.). The inventors have ascertained that a particularly suitable compromise between accuracy and speed of the method can be found, e.g., in the range of 10 to 300 data points. In this regard, determining the sample potential in the manner described herein can be carried out particularly robustly, reliably and rapidly.

In one exemplary embodiment, determining the potential can furthermore comprise extrapolating and/or determining a zero of the fit function.

The principal feature here is that this enables not only good interpolation but also extrapolation, e.g., it is thus possible to determine a point of intersection of a fit function (e.g., of a straight line) outside the first range (e.g., from −10 V to +10 V). Where the function intersects the abscissa, the minimum of the deflection can be determined, which is what can determine the sample potential. The inventors have recognized that astonishingly accurate potential determinations can be achieved by use of such fitting, even for extrapolations far away from the first range.

By way of example, the fit function can comprise a linear function, and preferably a correction of the linear function at least partly on the basis of the resonant frequency, an oscillation quality, and/or a spring constant of the probe.

In initial tests, calculations and simulations, the inventors have recognized that especially for distances between probe and sample of less than 10 μm, the electrostatic forces can be so strong that the resonant frequency changes significantly during the variation/application of the DC voltage offset (also called “sweep”/“sweeping”) and the applied AC voltage can then correspond to a non-resonant excitation. As a result, the measured signal (e.g., the deflection as a function of the applied DC voltage offset) can comprise a signal which to a good approximation is a linear signal or a non-linear signal. In the non-linear case, it can therefore be advantageous to include a correction of the linear function in the fit function or to use a non-linear fit function. In one exemplary embodiment, the fit function can therefore be based at least partly on the distance between sample and probe.

In one exemplary embodiment, the positioning can be carried out such that the distance between the probe and the sample can be 0.001 μm to 1000 μm, preferably 50 μm to 150 μm. In some examples, a minimum distance of 0.01 μm, 0.1 μm, 1 μm or 10 μm can also be provided.

As described herein, it has been found that the method can be carried out efficiently in these ranges: On the one hand, the distance between sample and probe is small enough that, e.g., the conditions provided for the linear relationship-described herein-between deflection and DC voltage offset or for reasonable estimations of the correction of the linear function (also outside the first range) are met and/or the forces between sample and probe are strong enough for reliably carrying out the method. On the other hand, sample and probe are spaced apart from one another far enough that a collision of sample and probe can be excluded or avoided with high probability. Possible non-linearities may occur as described herein and typically become noticeably apparent outside the first range. However, they can be incorporated just the same in the methods described herein, by being taken into account computationally.

A second aspect of the present invention relates to a method for causing approach by a probe towards a sample, wherein the method comprises: causing approach by the probe towards the sample; repeatedly determining a deflection of the probe during the process of causing approach; and ascertaining an approach termination condition for avoiding sample damage at least partly on the basis of the deflection of the probe.

The detection of excessively high mask potentials that is achieved by the first aspect can indeed serve for avoiding damage to the sample, but it does not always suffice to enable the sample also to be repaired in a succeeding step, which is the actual goal. This problem is addressed by the second aspect. Whereas conventional methods assume that, e.g., after discharging of a sample surface, the latter is uniformly discharged, the inventors have recognized that even after such discharging, there may still be local charges on the sample, as a result of which the sample and the probe cannot be safely caused to approach one another. The inventors have recognized that such local charges may still be high enough that these local charges may give rise to considerable damage to the sample and/or probe. This fact is aggravated since most methods for measuring sample potentials comprise large-area measurements which typically yield average values over areas which are very large in comparison with an area addressed by a probe (e.g., comparable with the cross section of a probe tip). Such average values do not contain any information about possible local charges. However, if the probe is caused to approach towards the sample, or even brought into contact therewith, exactly at or in the vicinity of such a local charge, damage to sample and/or probe typically occurs even in the case of a previous large-area discharge of the sample. Even if such cases generally do not occur, it is however greatly preferable to be able to ascertain and avoid these cases at an early stage, especially in the case of very expensive samples such as, e.g., EUV masks.

By way of example, the ascertaining can be carried out by use of a real-time device configured to ascertain the approach termination condition in 2 ms or less, preferably 1 ms or less, particularly preferably 0.5 ms or less.

Such rapid ascertaining of the approach termination condition can ensure that even at relatively high approach speeds allowing rapid processing, an unwanted collision can be avoided.

The method can, for example, furthermore comprise terminating the process of causing approach by the probe towards the sample at least partly on the basis of ascertaining the approach termination condition.

Defining an approach termination condition can constitute an objective decision basis, which can make the method safer and equally reliable independently of a user. Ascertaining the approach termination condition can take place automatically, for example, which can facilitate a user's work and accelerate the method and also make it more reliable and safer.

In one exemplary embodiment, the terminating can be carried out within 2 ms or less, preferably 1 ms or less, particularly preferably 0.5 ms or less, after occurrence of the approach termination condition.

Such rapid terminations of the approach can ensure that even at relatively high approach speeds allowing rapid processing, an unwanted collision can be avoided.

The process of causing approach by the probe can be carried out, for example, at a speed of 0.1 μm/s or more, preferably 1 μm/s or more, particularly preferably 2 μm/s or more.

That can reduce the required processing time of the sample and can thus save time and costs.

In one exemplary embodiment, the approach termination condition can comprise overshooting of a predefined deflection of the probe.

The inventors have ascertained that the deflection (e.g., the amplitude of an oscillation, the bending of a part of the probe, e.g., as described herein measured using a photodiode and a light beam reflected at the probe), for sufficiently large distances between probe and sample, remains in a predetermined range (e.g., within the scope of vibrations induced by the surroundings). Consequently, the overshooting of a predefined deflection constitutes a particularly reliable approach termination condition, which can apply both to static procedural avenues (without induced oscillation of the probe) and to dynamic procedural avenues (with induced oscillation of the probe) of this method as described herein.

The method can, for example, furthermore comprise determining a resonant frequency of the probe during the process of causing approach.

In one exemplary embodiment, the approach termination condition can comprise overshooting of a predefined frequency shift of the resonant frequency.

The inventors have recognized that a shift to lower (higher) frequencies occurs in conjunction with attractive (repulsive) forces, and have exploited this. Surprisingly, it has emerged that this procedural avenue is very sensitive, and so the approach termination can be implemented sufficiently rapidly on the basis thereof.

For example, the approach termination condition can comprise undershooting of a predefined minimum frequency by the resonant frequency.

For electrostatic forces as a consequence of a potential difference between sample and probe, an attractive force and hence a shift to lower frequencies will occur. Consequently, it is possible to define a minimum frequency whose undershooting can serve as a termination condition which can be particularly simple and reliable.

A third aspect of the present invention relates to methods for processing a sample, comprising: steps of a method for potential determination, as described herein; and at least partly on the basis of the potential determination, steps of a method for causing approach by a probe towards a sample, as described herein.

The combination of the methods for potential determination and for causing approach by the probe towards the sample is advantageous in many different respects: Firstly, it can thus be ensured that from the outset approach is caused only if the potential determination indicates that this is able to be carried out safely with high probability. Secondly, exactly the probe whose approach is intended to be caused later is used for potential determination, which is a particularly material-, time- and cost-saving procedural avenue.

For example, methods described herein can furthermore comprise at least partly discharging the sample at least partly on the basis of the potential determination.

The discharging can comprise, e.g., discharging as described in DE 10 2013 212 957 A1, the entire content of which is herein incorporated by reference.

By way of example, the discharging can be carried out for a potential of ±1 V or more, preferably ±5 V or more, particularly preferably ±10 V or more.

In this case, the “or more” should be understood as relative to the absolute value of the potential. A potential of ±1 V or more thus corresponds, e.g., to a potential of −1 V or less or +1 V or more. It can thus be ensured that discharging is effected whenever the potential is too high for possible subsequent method steps—e.g., causing approach by the probe towards the sample.

In one exemplary embodiment, the steps of the method for causing approach by the probe towards the sample can be carried out only for a potential of ±20 V or less, preferably ±15 V or less, particularly preferably ±10 V or less.

It can thus be ensured that the probe can be caused to approach the sample safely with relatively high probability.

The sample can be, e.g., at least partly electrically charged. That can be caused by, e.g., processing of the sample using a particle beam (e.g., an ion and/or electron beam) and/or observation of the sample (e.g., using a transmission electron microscope and/or a scanning electron microscope).

For example, the probe can comprise a probe of a scanning probe microscope, the probe can comprise a probe arm and/or a measuring tip, and/or the deflection can be measured by way of a light beam reflected at the probe.

The use of a probe (e.g., that of a scanning probe microscope), in particular with a deflection measurement by use of a reflected light beam, affords a number of technical advantages: The measurement of the deflection of the probe arm makes it possible to capture the surface structure of the sample extremely precisely. This results in a very high spatial resolution, which can extend into the atomic range. The method is extremely sensitive to small forces and displacements. This makes it possible to detect very fine topographic and mechanical properties of the sample. Scanning probe microscopes can be operated in various modes, such as, e.g., contact mode, tapping mode and/or non-contact mode, depending on the specific requirements of the examination. This makes them usable in diverse ways for various kinds of samples and applications. Since the measurement of the deflection of the probe arm generally does not cause any significant physical alteration of the sample, sensitive or valuable samples can be examined without damage thereto. Besides the topographic imaging, scanning probe microscopes can also measure other physical properties of the sample, such as, e.g., electrical, magnetic or mechanical properties, by said microscopes using corresponding probes and measurement methods. The deflection of the probe arm can be measured and analyzed in real time, which enables immediate feedback about the properties of the sample and facilitates the adaptation of the measurement parameters during the experiment. Examples of scanning probe microscopes and corresponding probes are described in U.S. Pat. No. 11,237,185 B2, the entire content of which is herein incorporated by reference.

The sample can comprise, e.g., an object for lithography, preferably a lithographic mask. The sample can be a photolithographic mask. The sample or the photolithographic mask can have an aspect ratio of between 1:1 and 1:4, preferably between 1:1 and 1:2, and particularly preferably of 1:1 or 1:2. The sample or the photolithographic mask can have an almost rectangular shape. The sample or the photolithographic mask can preferably have a length and width of 5 to 7 inches, particularly preferably a length and width of 6 inches. Alternatively, the sample or the photolithographic mask can also have a length of 5 to 7 inches and a width of 10 to 14 inches, preferably a length of 6 inches and a width of 12 inches.

The use of such probes is particularly advantageous precisely in the context of such objects for lithography, since the advantages mentioned above are extremely relevant when dealing with corresponding samples-especially dealing with the sample gently without damaging it.

A fourth aspect of the present invention relates to a device for processing the sample. The device comprises one or more means configured to automatically carry out the steps of one or more methods described herein.

The automation enables the methods described herein to be carried out consistently and repeatably. This reduces human errors and ensures a high accuracy and reproducibility of the results, which is of crucial importance especially in quality control and in scientific investigations. The automation additionally enables complex and time-consuming processes, such as, e.g., the methods described herein, to be carried out more rapidly and more efficiently. This leads to a considerable reduction of the processing time and enables a higher throughput rate, which can reduce costs. Automated systems reduce the need for manual interventions and thus minimize the variability that can be caused by different operators. This leads to a uniformly high quality of the results and reduces the risk of operating errors, which increases the reliability and safety of the methods.

The aspects described herein may be used with various samples.

The samples referred to in this application may, for example, comprise various types of substrates, e.g., semiconductor substrates, such as semiconductor industry substrates. In some examples, samples may include objects for lithography.

The samples referred to herein may further comprise reticles (including, e.g., various formats such as 6×6 inch, 6×12 inch, and 12×12 inch dimensions, with or without pellicles), nanoimprint lithography (NIL) templates or stamps, e.g., used for nanoscale pattern replication.

Additionally or alternatively, the aspects described herein may be used with samples such as wafers. The wafers may be provided in various sizes and/or cuts. The wafers may comprise, e.g., Si, SiO, sapphire, SiC, GaN, InP, Ge, GaAs, AlGaAs, ZnO, or CdS. The samples may further comprise wafers containing unique or non-uniform structures per chip, wafers having both structured and unstructured regions, partially processed or preprocessed wafers that have undergone one or more fabrication steps, and/or diced wafers (e.g., mounted on frames such as 380 mm frames). Additional applicable substrate types include, e.g., packaging substrates used in semiconductor packaging processes, dies, interposers, circuit boards, substrates subject to circuit editing applications, photonic integrated circuits, and hybrid electro-optical circuit substrates that combine electronic and optical functionalities. The methods and devices described herein are also applicable to, e.g., microfluidic systems including lab-on-a-chip devices, metamaterial substrates (which may be characterized by engineered properties, e.g., negative refractive index), and substrates comprising advanced nanomaterials, e.g., 2D materials, nanosheets, or topological insulators. In some possible examples, the samples may be samples for quantum computing applications (e.g., chips comprising one or more qubits or other quantum information processing elements) or for artificial intelligence and machine learning applications, e.g., where specialized electronic circuit architectures are employed.

A further aspect of the present invention relates to a computer program comprising instructions for execution of the steps of at least one of the methods described herein. A computer program can be written in any form of a programming language, including compiled or interpreted languages, and can be provided in any form, including as a standalone program or as a module, component, subroutine, or other entity suitable for use in a computer environment.

The embodiments of the present invention described herein and the features and properties mentioned optionally in this respect should likewise be understood as disclosed in all combinations with one another. In particular, the description of a feature comprised by an embodiment—provided there are no explicit explanations to the contrary—should also not be construed in the present case as meaning that the feature is indispensable or essential to the function of the embodiment. Likewise, features described herein in regard to steps of a method can be implemented as instructions of a computer program and means of a device, and vice versa.

### DESCRIPTION OF DRAWINGS

FIG. 1A shows a schematic illustration of a harmonic approximation of the force induced by the applied AC voltage as a function of the DC voltage offset.

FIG. 1B shows a schematic illustration of a probe and a sample and also the induced oscillation of the probe relative to the sample.

FIG. 2 shows a schematic illustration of the deflection, specifically the amplitude, the in-phase component, the quadrature component and the phase as a function of the applied DC voltage offset.

FIG. 3A shows a schematic illustration of those components of an exemplary device which can be used for control and sample potential determination.

FIG. 3B shows an exemplary probe and how it can be connected to the components from FIG. 3A.

FIG. 4 shows an exemplary comparison of two scenarios in which a probe with applied AC voltage at different distances from the sample has different resonant frequencies.

FIG. 5 shows an exemplary flowchart of an exemplary method according to the invention which combines a plurality of aspects described herein.

### DETAILED DESCRIPTION

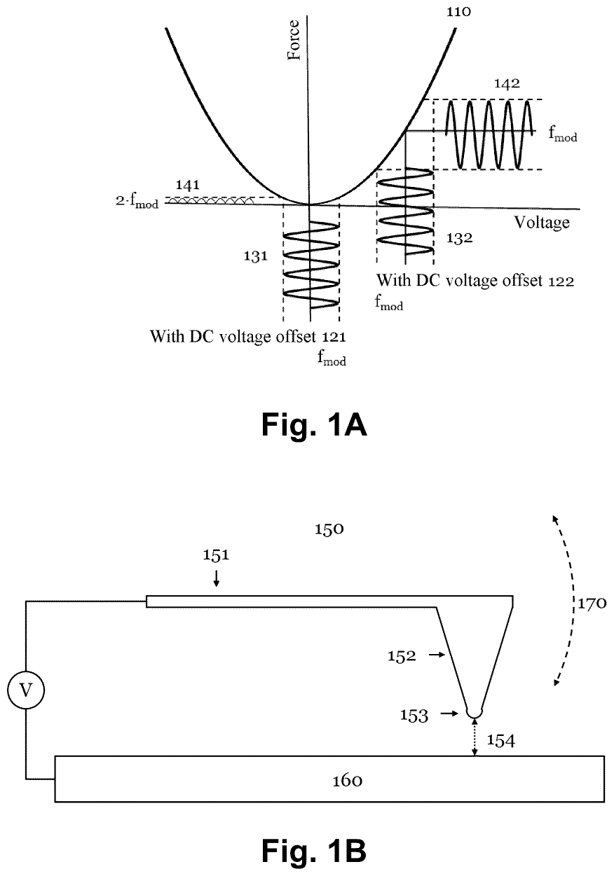

FIG. 1B shows a schematic illustration of a probe 150 and a sample 160 and also the induced oscillation 170 of the probe 150 relative to the sample 160. The probe 150 can be, e.g., part of a device for processing the sample 160. In this case, the probe has a probe arm 151, which at one end can be secured, e.g., to a movement stage (also called “stage” herein). The movement stage or the stage can be configured, e.g., to move the probe 150 in the x-, y- and/or z-direction and/or to rotate it along one or more angles. The movement stage can comprise, e.g., a 6DOF movement stage, i.e., a movement stage having six degrees of freedom. In the example in FIG. 1B, the measuring tip 152 having the tip end point 153 is situated at the other end of the probe arm 151. For example, the first and second DC voltage offsets described herein can be applied between probe 150 and sample 160. In order to induce the mechanical oscillation, an AC voltage may be applied to the probe in addition to the DC voltage offset. Then, the total time-varying voltage between the probe and the sample is the sum of the DC voltage offset (U_DC) and the time-varying AC voltage (U_AC sin(ωt)). The frequency of this AC voltage is typically chosen to be a resonance frequency of the probe or, for example, a multiple thereof, to achieve a high oscillation amplitude and thus high sensitivity. When the DC voltage offset is varied, for example during a “sweep” between the first and second DC voltage offsets, the amplitude and frequency of the AC voltage can be kept constant. The measuring tip 152 having the tip end point 153 can carry out a mechanical oscillation, represented (in a greatly enlarged fashion) by the dashed double-headed arrow 170, by virtue of the probe arm 151 being periodically bent or oscillating up and down in the illustration in FIG. 1B. As a result, the distance 154 between the measuring tip 152 or tip end point 153 and the sample 160 correspondingly changes periodically. This can correspond to the first and/or second deflection described herein.

For example, the probe 150 can be made of materials typically used for probes used for atomic force microscopy (AFM) or scanning electron microscopy.

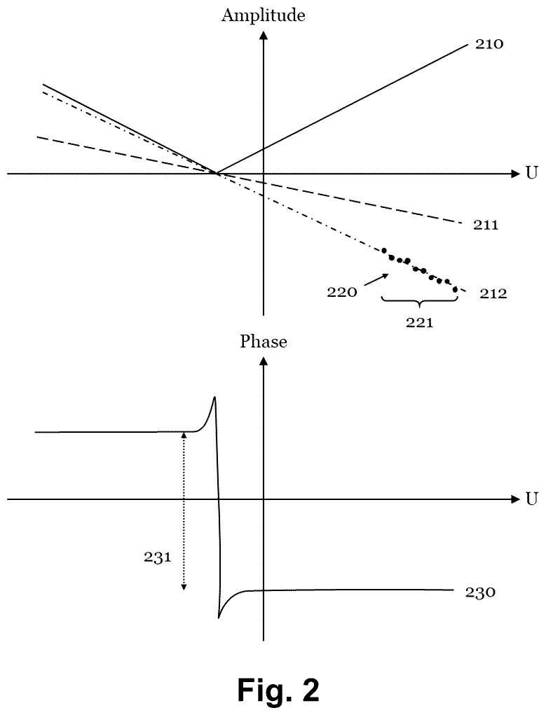

FIG. 2 shows a schematic illustration of the deflection of the probe arm 151, specifically the amplitude 210 of the deflection, the in-phase component (X) 212 of the deflection, the quadrature component (Y) 211 of the deflection, and the phase 230 of the deflection as a function of the applied DC voltage offset (U).

A lock-in amplifier is a device used to measure signals that are hidden in a highly noisy environment. It works using phase-sensitive detection in order to separate the signal from the noise. The in-phase component 212 and the quadrature component 211 are two essential parts of this process.

The in-phase component (X-component) 212 is the projection of the input signal, possibly given by the measured deflection, onto the reference signal wave which is in phase with the input signal. The in-phase component (X-component) represents that part of the input signal which directly matches the reference phase. The in-phase component is obtained mathematically by multiplication of the input signal by a sine reference signal and subsequent low-pass filtering. The in-phase component can provide information about the amplitude of the input signal which is in phase with the reference signal. The quadrature component (Y-component) 211 is the projection of the input signal onto a reference signal wave which is phase-shifted by 90 degrees (i.e., in quadrature with the reference phase). The quadrature component represents that part of the input signal which is phase-shifted by 90 degrees with respect to the reference phase. The quadrature component is obtained mathematically by multiplication of the input signal by a cosine reference signal and subsequent low-pass filtering. The quadrature component can provide information about the amplitude of the input signal which is in quadrature with the reference. At least some of the mathematical operations mentioned above may be realized by the lock-in amplifier setup. The reference signal may be generated using a signal generator which may be part of the lock-in amplifier setup.

In this case, the corresponding theoretical profile of the amplitude 210 of the deflection shows a V-shaped profile and the quadrature component (Y-component) 211 and also the in-phase component (X-component) 212 each show a linear profile, which all have the same zero crossing or zero point, which in theory corresponds to the sample potential. Consequently, the amplitude 210, the quadrature component (Y-component) 211 and/or the in-phase component (X-component) 212 can be fitted by a corresponding function in order to determine the zero (e.g., for the amplitude 210) or the zero crossing (e.g., for the quadrature component (Y-component) 211 and/or the in-phase component (X-component) 212, i.e., hence the sample potential.

The phase of the deflection has a 180° jump 231 at the sample potential. The phase can be fitted by a corresponding function in order to determine the zero crossing, i.e., hence the sample potential.

In the example in FIG. 2, the first range 221 is the range containing the measurement points 220. The exemplary plurality of DC voltage offsets comprises a first, a second and further DC voltage offsets in the first range 220. In the example in FIG. 2, only the measurement points for the in-phase component (X-component) 212 are illustrated and the dot-dashed line represents a fit of these measurement points 220. Extrapolation makes it possible to determine the zero, i.e., the mask potential that is outside the interval (the first range) spanned by the plurality of DC voltage offsets. In this case, the first range can be, e.g., in the interval of −10 V to +10 V and the mask potential determined can be, e.g., at absolute voltage values higher than 10 V.

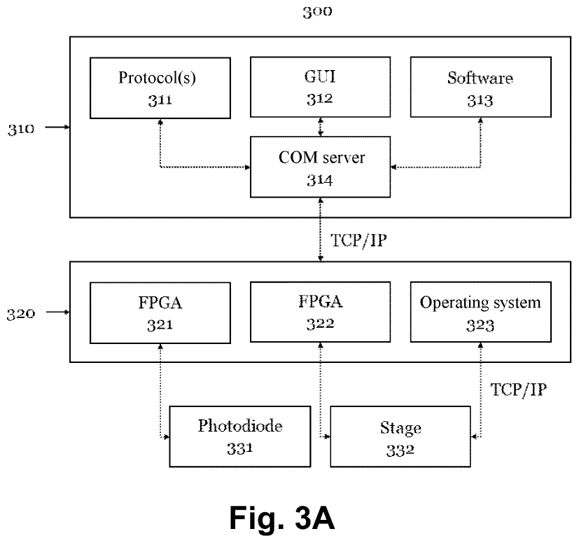

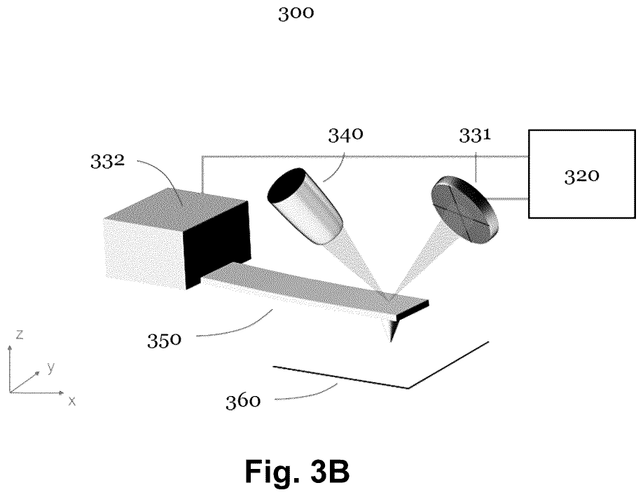

FIG. 3A shows a schematic illustration of those components 310, 320, 331, 332 of an exemplary device 300 which can be used for control and sample potential determination.

In this case, the exemplary device 300 in FIG. 3A comprises a computer 310. In some implementations, the device 300 and/or the computer can comprise a data processor and a storage medium. The data processor can be configured, e.g., to execute the method steps described herein and/or to provide the mechanical and/or electronic components involved with instructions for executing the steps. The storage medium can store the herein described data, information, software 313, protocols 311, etc., for executing the methods described herein. As an interface therefor, e.g., a COM server 314 can be provided. A COM server (component object model server) 314 can comprise, e.g., a software component which is based on COM technology and can provide services or functions for other applications. This component can communicate with a further unit 320 (e.g., a controller for the aforementioned mechanical and/or electronic components 331, 332) by way of IP and/or TCP protocols, for example. In some implementations, the device 300 can comprise one or more computers 310 containing one or more data processors configured to execute one or more programs containing a variety of instructions according to the principles described above. Each data processor can contain one or more processor cores, and each processor core can contain logic circuits for data processing. By way of example, a data processor can comprise an arithmetic logic unit (ALU), a control unit and various registers. Each data processor can contain a cache memory. Each data processor can contain a system-on-chip (SoC) containing a plurality of processor cores, a random access memory (RAM), graphics processors, one or more controllers, and one or more communication modules. Each data processor can contain millions or billions of transistors.

The controller 320 can comprise, e.g., one or more field programmable gate arrays (FPGAs) 321, 322 and/or a controller-inherent operating system 323 in order, in the example of the present invention, e.g., to control the photodiode 331 and/or the stage 332 and/or to receive the data recorded thereby (e.g., the deflection of the probe arm 151 detected by the photodiode 331). The recorded data can then be provided to the computer 310, e.g., via the IP/TCP interface.

The methods described in this document can be carried out by one or more computers 310 containing one or more data processors for data processing, one or more storage media for data storage and/or one or more computer programs comprising instructions which, when executed by the one or more computers, cause the processes to be carried out. The one or more computers can comprise one or more input devices, such as, e.g., a keyboard, a mouse, a touchpad, and/or a voice command module, and one or more output devices, such as, e.g., a display and/or a loudspeaker. Accordingly, a graphical user interface 312 can be provided, via which a user can initiate, stop, pause and/or at least partly control or influence the execution of the methods described herein.

In some implementations, the one or more computing devices can comprise digital electronic circuits, computer hardware, firmware, software, or a combination of the aforementioned elements. The features for data processing can be implemented in a computer program product that is materially embodied in an information carrier, e.g., in a machine-readable storage medium, for execution by a programmable processor; and method steps can be executed by a programmable processor that executes a program of instructions in order to fulfil the functions of the implementations described. Alternatively or additionally, the program instructions can be encoded in a propagated signal that is an artificially generated signal, e.g., a machine-generated electrical, optical or electromagnetic signal, which is generated in order to encode information for transmission to a suitable receiving device in order to be executed by a programmable processor.

By way of example, the one or more computers can be configured to be suitable for the execution of a computer program, and they can comprise general and specialized microprocessors and any desired processors of any type of digital computer. In general, a processor receives instructions and data from a read-only memory or a random access memory, or both. Elements of a computer system comprise one or more processors for executing instructions and one or more storage devices for storing instructions and data. In general, a computer system also comprises, or is operatively coupled thereto, in order to receive data from one or more machine-readable storage media or to transmit data thereto, or both, such as, e.g., hard disks, magnetic disks, solid-state drives, magneto-optical disks or optical disks. Machine-readable storage media suitable for embodying computer program instructions and data comprise various forms of non-volatile memories, including, for example, semiconductor memory devices, e.g., EPROM, EEPROM, flash memory devices, and solid-state drives; magnetic disks, e.g., internal hard disks or removable disks; magneto-optical disks; and CD-ROM, DVD-ROM and/or Blu-ray discs.

In some implementations, the processes described above can be executed with the aid of software executed on one or more mobile computing devices, one or more local computing devices and/or one or more remote computing devices (which can be, e.g., cloud computing devices). For example, the software methods form one or more computer programs that are executed on one or more programmed or programmable computer systems, either on the mobile computing devices, local computing devices or remote computing systems (which can comprise various architectures, such as distributed systems, client/server systems, grid systems or cloud systems), each comprising at least one processor, at least one data storage system (including volatile and non-volatile storage and/or storage elements), at least one wired or wireless input device or port, and at least one wired or wireless output device or port.

In some implementations, the software can be provided on a medium, such as, e.g., CD-ROM, DVD-ROM, Blu-ray Disc, a solid-state drive or a hard disk, which can be read by a general or special programmable computer, or can be transmitted via a network (in a manner encoded in a propagated signal) to the computer where it is executed. The functions can be executed on a specific computer or with the aid of specific hardware, such as, e.g., coprocessors. The software can be implemented in a distributed manner in which different parts of the calculations specified by the software are executed by different computers. Any such computer program is preferably stored or downloaded on a storage medium or a storage device (e.g., solid-state storage or storage media or magnetic or optical media), which can be read by a general or specific programmable computer in order to configure and operate the computer system upon reading by use of the computer system such that the methods described herein are executed. The system according to the invention can also be considered to be a computer-readable storage medium configured with a computer program, wherein the storage medium configured in this way causes the computer system to implement the functions described herein, in a specific and predefined manner.

FIG. 3B shows an exemplary probe 350, for example of a device for processing a sample 360, and how said probe can be connected to the components 331, 332 from FIG. 3A. In the illustration in FIG. 3B, the probe is positioned above the sample 360 essentially as in FIG. 1B, e.g., by use of the stage 332. The light source 340 is configured to direct a light beam at the probe, e.g., at a top side of the reflective probe arm, such that the reflected signal can be recorded by the photodiode 331 and forwarded to the controller 320, for example.

The photodiode 331 can be, e.g., a four-quadrant photodiode (4Q photodiode) and/or can play an important part (such as, e.g., in an atomic force microscope (AFM)) for the measurement of the deflection of the probe arm: As described herein, the probe arm can reflect the light beam or laser beam, such that said beam can impinge on the surface of the four-quadrant photodiode. The photodiode can be subdivided into four separate regions (quadrants), each of which can capture a portion of the reflected laser beam. These quadrants are typically designated as A, B, C and D. If the probe arm is deflected on account of interactions with the sample surface, the position of the reflected laser beam on the photodiode changes. This change results in different intensities of the light which impinges on the individual quadrants. The photodiode can generate, e.g., electrical signals that are proportional to the light intensity in each quadrant. By comparing the signals of the different quadrants, it is possible to calculate the deflection of the probe arm in two dimensions (vertically and laterally): The difference in the signals between the upper (A+B) and lower (C+D) quadrants indicates the vertical deflection of the probe arm. The difference in the signals between the left (A+C) and right (B+D) quadrants indicates the lateral deflection of the probe arm.

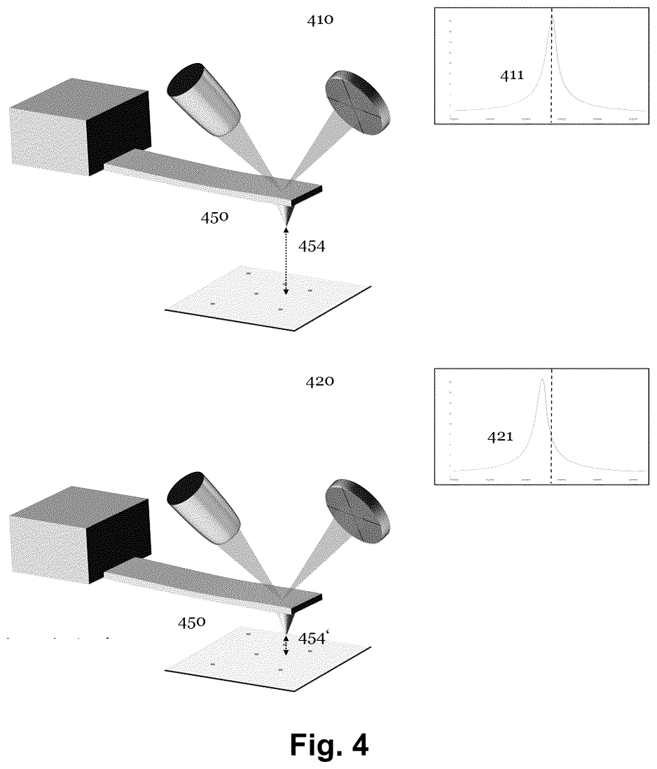

FIG. 4 shows an exemplary comparison of two scenarios in which a probe 450 with applied AC voltage at different distances 454, 454′ from the sample has different resonant frequencies. These scenarios can occur, e.g., in the methods described herein for causing approach by a probe 450 towards a sample 460.

In the upper region 410 in FIG. 4, the probe 450 is at a first (large) distance 454 away from the sample. The profile 411 of the amplitude of the induced oscillation as a function of the frequency is illustrated to the right thereof. The frequency with the highest amplitude is at approximately 300,000 Hz in this example.

In the lower region 420 in FIG. 4, the probe 450 is at a second (small) distance 454′ away from the sample, e.g., after or during a process of causing approach by the probe 450 towards the sample 460. The profile 421 of the amplitude of the induced oscillation as a function of the frequency is illustrated to the right thereof. The frequency with the highest amplitude is at approximately 299,990 Hz in this example, and thus red-shifted with respect to the case illustrated in the upper region 410.

FIG. 4 thus schematically illustrates how the frequency shift can occur as a function of the distance 454, 454′ between probe 450 and sample.

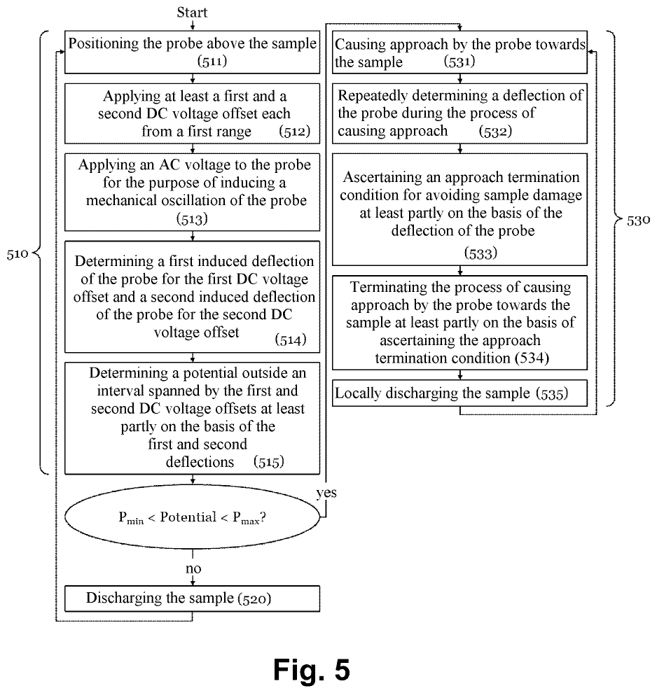

FIG. 5 shows an exemplary flowchart of an exemplary method according to the invention which combines a plurality of aspects described herein.

The method in FIG. 5 can be subdivided into three aspects: a method for potential determination pertaining to a sample 510, a method for discharging the sample 520 and a method for causing approach by a probe towards the sample 530.

The method for potential determination pertaining to a sample 510 comprises steps 511-515: The method can start by the probe being positioned 511 above the sample. Afterwards, at least a first and a second DC voltage offset each from a first range can be applied 512. As described herein, the first DC voltage offset can be applied at a first point in time and the second DC voltage offset can be applied at a second point in time (different from the first point in time) (e.g., temporally before or after the first point in time). Moreover, the method 512 comprises applying an AC voltage to the probe for the purpose of inducing a mechanical oscillation of the probe 513, and determining a first induced deflection of the probe for the first DC voltage offset and a second induced deflection of the probe for the second DC voltage offset 514. In some implementations, the amplitude and frequency of the AC signal for inducing the first deflection can be the same as the amplitude and frequency of the AC signal for inducing the second deflection. On the basis 15 thereof, it is possible to determine 515 a potential P outside an interval spanned by the first and second DC voltage offsets at least partly on the basis of the first and second deflections. On the basis of whether or not the potential P thus determined is in the range “Pₘᵢₙ<P<Pₘₐₓ”, afterwards it is possible to continue with the approach by the probe towards the sample 531 or to discharge the sample 520. In this case, Pₘᵢₙ can correspond to a lower threshold and Pₘₐₓ can correspond to an upper threshold, wherein given a potential P (of the sample) in the range Pₘᵢₙ<P<Pₘₐₓ (i.e., above the lower threshold Pₘᵢₙ and below the upper threshold Pₘₐₓ) it can be assumed that a safe approach is possible. For example, Pₘᵢₙ can be −1 V, −5 V, −10 V or −20 V and/or Pₘₐₓ can be 1 V, 5 V, 10 V or 20 V. In other examples, it is also possible to use other predetermined values of Pₘᵢₙ and/or Pₘₐₓ.

If the potential is in a range in which it is assumed that the sample potential is too high to be able to cause the probe to approach safely (i.e., outside [Pₘᵢₙ, Pₘₐₓ]), a decision can be taken to discharge the sample: In the example in FIG. 5, the method for discharging the sample 520 comprises merely discharging the sample (e.g., according to known methods and/or methods described herein). This discharging can be performed, e.g., using a glow discharge process. In this method, a glow discharge unit is positioned in the vicinity of the sample. This unit typically comprises two electrodes and a system for introducing and removing a process gas. A high-frequency alternating voltage is applied across the electrodes in the presence of a low-pressure gas stream. This ionizes the gas, creating a plasma that contains a mixture of positive ions and electrons. The charged particles from this plasma are then attracted to the electrostatically charged surface of the sample, where they neutralize the potential. For instance, if the sample surface is negatively charged from prior electron beam exposure, it will attract positive ions from the plasma to restore a neutral state.

In particular in terms of its duration, intensity, carrying out, etc., the discharging can be based on the sample potential determined. Specifically, the parameters of the sample discharge can be set such that it can be assumed that the sample potential essentially vanishes as a result of the discharging. Afterwards, the method 510, e.g., as illustrated in FIG. 5 (beginning with step 511 or, e.g., step 512 (if the probe is already correctly positioned)) can be carried out again. This loop can take place as often as desired until the sample potential is in the range [Pₘᵢₙ, Pₘₐₓ].

If the sample potential is in the range [Pₘᵢₙ, Pₘₐₓ] (with or without prior discharging 520), the method for causing approach by a probe towards the sample 530 can be carried out. This method comprises the steps 531-535: causing approach by the probe towards the sample 531 and repeatedly determining a deflection of the probe during the process of causing approach 532, e.g., at a predefined rate. At least partly on the basis of the deflection of the probe, an approach termination condition for avoiding sample damage can be ascertained 533 (or not ascertained). If an approach termination condition is ascertained, the process of causing approach by the probe towards the sample can be terminated (534) and/or the sample can be (locally) discharged 535. Since method 530 can ascertain very local sample potentials in the course of causing approach (in comparison with the relatively large-area scanning of the surface by use of method 510), sample potentials that remained undetected in method 510 can thus be captured. After the discharging of the sample 535, the process of approaching the sample 531 (together with the further steps 532-535) can be continued. This loop can take place as often as desired until the probe has been caused to approach towards the sample until reaching the target distance (e.g., until making contact).

A number of embodiments of the invention have been described. Nevertheless, it will be understood that various modifications may be made without departing from the spirit and scope of the invention. Accordingly, other embodiments are within the scope of the following claims.

What is claimed is:

1. A method for potential determination pertaining to a sample, wherein the method comprises:
positioning a probe above the sample;
applying at least a first and a second DC voltage offset each from a first range;
applying an AC voltage to the probe for the purpose of inducing a mechanical oscillation of the probe;
determining a first induced deflection of the probe for the first DC voltage offset and a second induced deflection of the probe for the second DC voltage offset; and
determining a potential outside an interval spanned by the first and second DC voltage offsets at least partly on the basis of the first and second deflections.

2. The method of claim 1, wherein the deflection comprises an amplitude of the mechanical oscillation and/or a phase of the mechanical oscillation.

3. The method of claim 1, wherein the first and second deflections comprise an in-phase component and/or a quadrature component.

4. The method of claim 1, wherein determining the first and second deflections comprises a lock-in amplification.

5. The method of claim 1, wherein the AC voltage frequency is substantially equal to or a multiple of a resonant frequency of the probe.

6. The method of claim 1, wherein the first range extends from −10 V to +10 V.

7. The method of claim 1, wherein determining the potential comprises fitting, using a fit function, at least a first data point comprising the first deflection and the first DC voltage offset and a second data point comprising the second deflection and the second DC voltage offset.

8. The method of claim 7, wherein determining the potential furthermore comprises extrapolating and/or determining a zero of the fit function.

9. The method of claim 7, wherein the fit function comprises a linear function, and preferably a correction of the linear function at least partly on the basis of the resonant frequency, an oscillation quality, and/or a spring constant of the probe.

10. The method of claim 1, wherein the positioning is carried out such that the distance between the probe and the sample is 0.001 μm to 1000 μm, preferably 50 μm to 150 μm.

11. A method for causing approach by a probe towards a sample, wherein the method comprises:
causing approach by the probe towards the sample;
repeatedly determining a deflection of the probe during the process of causing approach; and
ascertaining an approach termination condition for avoiding sample damage at least partly on the basis of the deflection of the probe.

12. The method of claim 11, wherein the ascertaining is carried out by use of a real-time device configured to ascertain the approach termination condition in 2 ms or less, preferably 1 ms or less, particularly preferably 0.5 ms or less.

13. The method of claim 11, further comprising terminating the process of causing approach by the probe towards the sample at least partly on the basis of ascertaining the approach termination condition.

14. The method of claim 13, wherein the terminating is carried out within 2 ms or less, preferably 1 ms or less, particularly preferably 0.5 ms or less, after occurrence of the approach termination condition.

15. The method of claim 11, wherein the process of causing approach by the probe is carried out at a speed of 0.1 μm/s or more, preferably 1 μm/s or more, particularly preferably 2 μm/s or more.

16. The method of claim 11, wherein the approach termination condition comprises overshooting of a predefined deflection of the probe.

17. The method of claim 11, furthermore comprising determining a resonant frequency of the probe during the process of causing approach.

18. The method of claim 17, wherein the approach termination condition comprises overshooting of a predefined frequency shift of the resonant frequency.

19. The method of claim 17, wherein the approach termination condition comprises undershooting of a predefined minimum frequency by the resonant frequency.

20. A method for processing a sample, comprising:
the steps of the method for potential determination of claim 1; and
at least partly on the basis of the potential determination, the steps of a second method for causing approach by a probe towards a sample, the second method comprising:
causing approach by the probe towards the sample;
repeatedly determining a deflection of the probe during the process of causing approach; and
ascertaining an approach termination condition for avoiding sample damage at least partly on the basis of the deflection of the probe.

21. The method of claim 20, furthermore comprising at least partly discharging the sample at least partly on the basis of the potential determination.

22. The method of claim 21, wherein the discharging is carried out for a potential of ±1 V or more, preferably ±5 V or more, particularly preferably ±10 V or more.

23. The method of claim 21, wherein the steps of the second method are carried out only for a potential of ±20 V or less, preferably ±15 V or less, particularly preferably ±10 V or less.

24. The method of claim 1, wherein the sample is at least partly electrically charged.

25. The method of claim 1, wherein the probe comprises a probe of a scanning probe microscope;
wherein the probe comprises a probe arm and a measuring tip and/or
wherein the deflection is measured by way of a light beam reflected at the probe.

26. The method of claim 1, wherein the sample comprises an object for lithography, preferably a lithographic mask.

27. A device for processing a sample, wherein the device comprises means configured to automatically carry out the steps of the method of claim 1.
